(19) United States
(12) Patent Application Publication
(10) Pub. No.: US 2022/0190210 A1
(43) Pub. Date: Jun. 16, 2022

(54) Light Emitting Lamp Bead and Lamp

(71) Applicant: FOSHAN NATIONSTAR OPTOELECTRONICS CO., LTD., Foshan, Guangdong (CN)

(72) Inventors: Yurong LI, Foshan, Guangdong (CN); Libing PAN, Foshan, Guangdong (CN); Fuhai LI, Foshan, Guangdong (CN); Zhiguo XIE, Foshan, Guangdong (CN)

(21) Appl. No.: 17/605,586

(22) PCT Filed: Nov. 29, 2019
(86) PCT No.: PCT/CN2019/122059

§ 371 Date: Oct. 22, 2021

(30) Foreign Application Priority Data
Apr. 29, 2019 (CN) 201910356836.8

(51) Int. Cl. H01L 33/50; F21K 9/64

(52) U.S. Cl. CPC H01L 33/504; F21K 9/64

(57) ABSTRACT

Disclosed is a light emitting lamp bead, in which a blue light missing portion is effectively filled by means of a chip excitation phosphor combination having the waveband of 400 nm-415 nm, and phosphors also has strong absorption for purple light, so that a light emitting diode (LED) device having high light emitting efficiency may be obtained. For the waveband of 420 nm-460 nm, a blue phosphor also achieves emission; however, because the phosphors have broad peak emission, the intensity is weak with respect to a blue light excitation position, so that the harm of blue light is reduced.

### CROSS-REFERENCE TO RELATED APPLICATION

The present disclosure is a national stage application of International Patent Application No. PCT/CN2019/122059, which is filed on Nov. 29, 2019, and claims priority to Chinese Patent Application No. 201910356836.8, filed on Apr. 29, 2019 and entitled “Novel Light Emitting Lamp Bead and Lamp”, the contents of which are hereby incorporated by reference in its entirety.

### TECHNICAL FIELD

The present disclosure relates to a technical field of light emitting devices, and particularly relates to a light emitting lamp bead, and a lamp using the lamp bead.

### BACKGROUND

A traditional light emitting diode (LED) lamp bead uses 440 nm-460 nm of blue light to excite phosphors to obtain white light. For the blue light as an excitation light source in a production of a high color temperature LED lamp bead, an intensity of blue light emission is high, and there is blue light hazards at 420 nm-460 nm, and at the same time, for the excitation of the blue light section, the 400 nm-440 nm section of a spectrum is missing. If this part of the spectrum is not compensated, the color rendering of R8, R12 and the like is apparently missing, it causes distortion to the color, and a true color of an illuminated object is not restored.

### SUMMARY

This technical scheme provides a light emitting lamp bead, in which a blue light missing portion is effectively filled by means of a chip excitation phosphor combination having the waveband of 400 nm-415 nm, and phosphors also have strong absorption for purple light, so that an LED device having high light emitting efficiency is obtained. For a waveband of 420 nm-460 nm, a blue phosphor is also achieve emission; however, because the phosphors have broad peak emission, an intensity is weak with respect to a blue light excitation position, so that a harm of blue light is reduced.

Some embodiments of the present disclosure is achieved through the following technical schemes: a light emitting lamp bead, including at least one light emitting element and phosphors excited by the at least one light emitting element, a main emission peak of each light emitting element is 400 nm-415 nm, and the phosphors include a blue phosphor, a green phosphor, a yellow phosphor and a red phosphor.

In some embodiments, an emission peak wavelength of the blue phosphor is 400 nm-480 nm, preferably MgSr₃Si₂O₈:Eu²⁺ with an emission peak waveband of 420 nm-460 nm; an emission peak wavelength of the green phosphor is 480 nm-520 nm, specifically Sr₅(PO₄)₃Cl:Eu²⁺; an emission peak wavelength of the yellow phosphor is 500 nm-560 nm, specifically Ga-YAG, LuAG or YAG; and an emission peak wavelength of the red phosphor is 590 nm-660 nm, specifically CaAlSiN₃:Eu²⁺.

While the light emitting lamp bead with a color temperature of 3000K is produced, the maximum light emitting energy intensity thereof in the wavelength range of 380 nm-430 nm is below 45%, the maximum light emitting energy intensity thereof in the wavelength range of 430 nm-480 nm is above 20%, and the maximum light emitting energy intensity thereof in the wavelength range of 630 nm-650 nm is 100%.

While the light emitting lamp bead with a color temperature of 5000K is produced, the maximum light emitting energy intensity thereof in the wavelength range of 380 nm-430 nm is 100%, the maximum light emitting energy intensity thereof in the wavelength range of 430 nm-480 nm is above 40%, the maximum light emitting energy intensity thereof in the wavelength range of 480 nm-600 nm is above 40%, and the maximum light emitting energy intensity thereof in the wavelength range of 600 nm-660 nm is above 40%.

While the light emitting lamp bead with a color temperature of 4000K is produced, the maximum light emitting energy intensity thereof in the wavelength range of 600 nm-700 nm is 100%, the maximum light emitting energy intensity thereof in the wavelength range of 440 nm-460 nm is below 60%, and the maximum light emitting energy intensity thereof in the wavelength range of 460 nm-480 nm is above 60%.

The light emitting energy intensity refers to the relative intensity of each wavelength range in a spectrum shown in a normalized mode by using the maximum peak value in the spectrum of the light emitting lamp bead as the reference intensity.

The above light emitting lamp bead is installed on a substrate, as to form a lamp with very high light emitting efficiency.

This technical scheme provides a light emitting lamp bead. Because the light emitting element with the main emission peak of 400 nm-415 nm is used to excite a mixture of four phosphors, it has the following advantages.

1. The light emission is very weak in the range of 420 nm-460 nm, and the blue light hazard is greatly reduced.

2. The intensity of the blue light in the range of 460 nm-480 nm is improved, so that a color is more vivid, and at the same time, after the intensity is improved, it has a positive effect on a human body in a specific using environment, such as stimulating melatonin and improving work efficiency.

3. In the wavelength range of 420 nm-660 nm, a spectrum with small fluctuation amplitude and excellent continuity is emitted, and the overall blue light is less and closer to sunlight compared with a traditional LED lamp bead, and the good illumination effect is provided for a user, so the users also get look and feel similar to outdoor activities during indoor activities.

### BRIEF DESCRIPTION OF THE DRAWINGS

Drawings constituting a part of the present application are used to provide further understanding of the present disclosure. Exemplary embodiments of the present disclosure and descriptions thereof are used to explain the present disclosure, and do not constitute improper limitation to the present disclosure. In the drawings:

FIG. 1 is a spectrum comparison of Embodiment 1 with a color temperature of 4000K and Comparative Example 1.

FIG. 2 is a spectrum comparison of Embodiment 1 with the color temperature of 4000K and Comparative Example 2.

FIG. 3 is a spectrum comparison of Embodiment 1 with a color temperature of 2700K and Comparative Example 2.

FIG. 4 is a spectrum diagram of Embodiment 1 with a color temperature of 3000K.

FIG. 5 is a spectrum diagram of Embodiment 1 with a color temperature of 5000K.

### DETAILED DESCRIPTION OF THE EMBODIMENTS

The present disclosure is further described in detail below through specific embodiments in combination with the drawings. However, those skilled in the art may understand that the following embodiments are only used to illustrate the present disclosure, and should not be regarded as limiting a scope of the present disclosure. If a specific technology or condition is not indicated in the embodiment, it shall be performed according to the technology or condition described in documents in the field or according to a product specification. Reagents or instruments used without indicating a manufacturer are all conventional products that may be purchased commercially.

### Embodiment 1

A light emitting lamp bead, including at least one light emitting element and phosphors excited by the at least one light emitting element, wherein a main emission peak of each light emitting element is 400 nm-415 nm, and the phosphors include a blue phosphor with an emission peak wavelength range of 400 nm-480 nm and a FWHM (full width at half maxima) of 50 nm-90 nm, a green phosphor with an emission peak wavelength range of 480 nm-520 nm and a FWHM (full width at half maxima) of 50 nm-90 nm, a yellow phosphor with an emission peak wavelength range of 500 nm-560 nm and a FWHM (full width at half maxima) of 90 nm-110 nm and a red phosphor with an emission peak wavelength range of 590 nm-660 nm and a FWHM (full width at half maxima) of 70 nm-90 nm. Specifically, the phosphors include MgSr3Si2O8:Eu2+, Sr5(PO4)3Cl:Eu2+, Ga-YAG, and CaAlSiN₃:Eu²⁺. Phosphor mass ratio: MgSr₃Si₂O₈:Eu²⁺ accounts for 10%-30% of the total phosphor ratio; Sr₅(PO₄)₃Cl:Eu²⁺ accounts for 30%-50% of the total phosphor ratio; Ga-YAG accounts for 30%-50% of the total phosphor ratio; and CaAlSiN₃:Eu²⁺ accounts for 5%-15% of the total phosphor ratio. The light emitting element is installed in an LED bracket, and after the phosphors are mixed, they fill the LED bracket together with packaging glue.

In some embodiments, the red phosphor is CaAlSiN₃:Eu²⁺, or a (Sr/Ca)AlSiN₃:Eu²⁺ co-doped red phosphor.

### COMPARATIVE EXAMPLE 1

The lamp bead uses traditional phosphors excited by blue light, the phosphors include Ga-YAG powder with an emission peak of 500 nm-560 nm, nitride red powder with a peak wavelength of 640 nm-660 nm, and silicate blue-green powder with an emission peak of 480 nm-520 nm, as to make a high color rendering scheme. The formula has strong blue light emission at 440 nm-460 nm, and a spectrum is discontinuous after 460 nm.

### COMPARATIVE EXAMPLE 2

The main emission peak of the light emitting element used in the lamp bead is 400 nm-415 nm, and the phosphor scheme is a high color rendering scheme made by a scheme of halophosphate with an emission peak of 440 nm-520 nm, Ga-YAG with an emission peak of 520 nm-560 nm, and nitride red powder with an emission peak of 600 nm-660 nm. In this scheme, the blue light emission intensity is relatively low at 460 nm-480 nm, and the relative energy intensity is only about 40%.

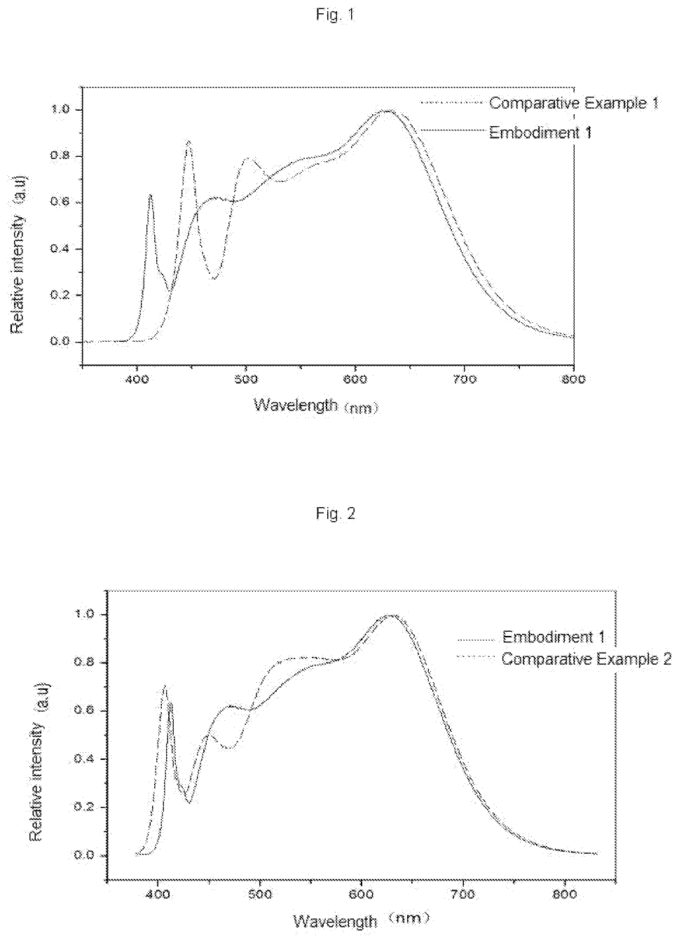

According to the matching range of Embodiment 1, it is modulated to obtain a light emitting lamp bead with a color temperature of 4000K, and a spectrum thereof is measured and compared with the spectrum of a product in Comparative Example 1. As shown in FIG. 1, the dotted line is a traditional blue light excitation spectrum, and the solid line is the spectrum of a product in Embodiment 1. As a representative of traditional blue light excitation, the spectrum of Comparative Example 1 with the color temperature of 4000K accounts for more than 80% of the blue light intensity in the wavelength range of 440 nm-460 nm, and it is much higher than the spectrum of the product of Embodiment 1, and is easy to damage a retina of a user. The maximum light emitting energy intensity of the product in the spectrum range of 600 nm-700 nm in Embodiment 1 is 100%, and the blue light intensity of the product in the spectrum wavelength range of 440 nm-460 nm accounts for less than 60%, it avoids the high blue light intensity from harming a human body. The spectrum of Comparative Example 1 is a trough in the waveband range of 460 nm-480 nm, and the energy intensity thereof is below 30%, it is quite different from a blackbody radiation spectrum, and it is difficult to provide the good color rendering quality. Since the waveband range of 460 nm-480 nm is a long-wave blue light waveband that has a positive effect on a biological rhythm of the human body, the energy intensity of the product of Embodiment 1 in the spectrum range of 460 nm-480 nm accounts for more than 60%, it provides sufficient energy intensity. Therefore, on the one hand, it guarantees a continuity of the spectrum and improves a light quality of the light emitting lamp bead, and on the other hand, it also helps the users actively adjust sleep, mood, memory and the like.

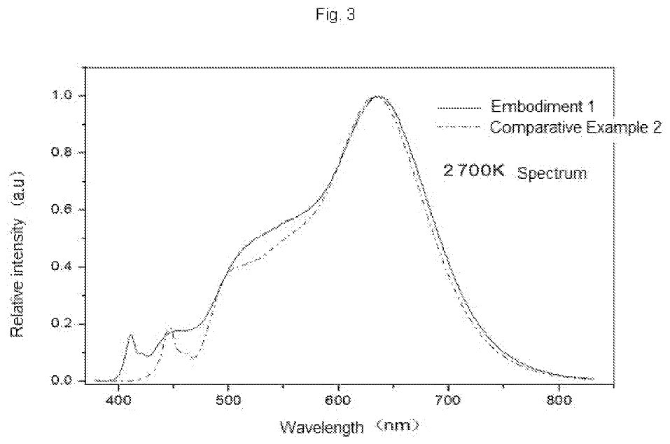

According to the matching range of Embodiment 1, it is modulated to obtain the light emitting lamp bead with a color temperature of 2700K, a spectrum thereof is measured and compared with the spectrum of a product of Comparative Example 2. As shown in FIG. 2, the blue light intensity of a traditional blue light scheme of Comparative Example 2 with the color temperature of 2700K is a narrow peak at 440-460 nm, and it affects a distribution of the light color. Compared with the spectrum shown in FIG. 3, the light emitting lamp bead of Embodiment 1 has an emission peak at 400 nm-420 nm, and a radiant energy of the entire spectrum of 400 nm-800 nm continuously rises.

Both comparisons show that the lamp bead provided in Embodiment 1 emits a spectrum with a small fluctuation amplitude and excellent continuity in the wavelength range of 420 nm-660 nm, it is closer to sunlight and provides a good illumination effect for the users.

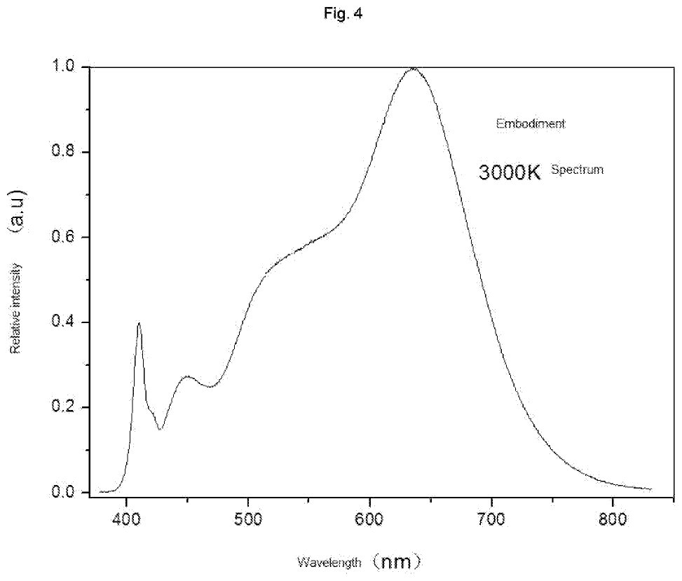

According to the matching range of Embodiment 1, it is modulated to obtain the light emitting lamp bead with a color temperature of 3000K, and a spectrum thereof is measured as shown in FIG. 4. There is a peak in the wavelength range of 380 nm-430 nm, so there is a maximum value in this range, and the light emitting energy intensity thereof is ≤45%; there is a trough in the wavelength range of 430 nm-480 nm, but the light emitting energy intensity thereof still is ≥20%; and the light emitting energy intensity in the wavelength range of 480 nm-650 nm continues to rise, and a maximum value of the energy intensity in the entire spectrum appears in the range of 630 nm-650 nm, namely, the maximum energy intensity in the range of 630 nm-650 nm is 100%.

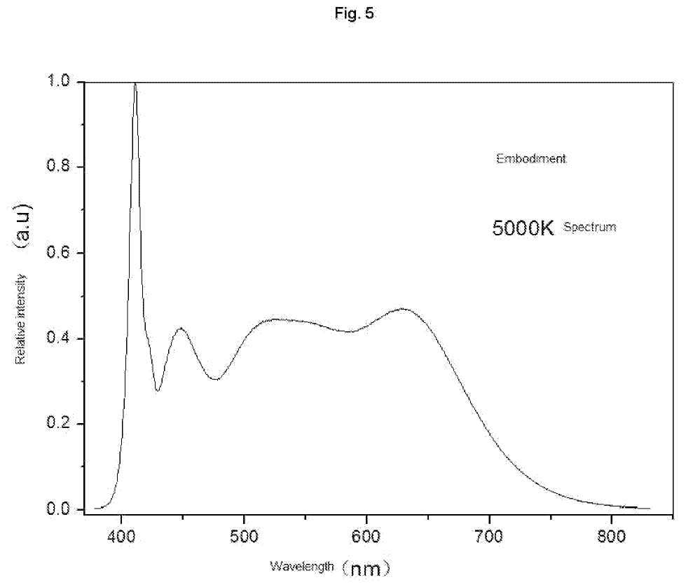

According to the matching range of Embodiment 1, it is modulated to obtain the light emitting lamp bead with a color temperature of 5000K, and a spectrum thereof is measured as shown in FIG. 5. The maximum value of the energy intensity in the entire spectrum appears in the wavelength range of 380 nm-430 nm, namely, the maximum energy intensity in the range of 380 nm-430 nm is 100%; there is a peak in the wavelength range of 430 nm-480 nm, so there is a maximum value in this range, and the light emitting energy intensity thereof is ≥40%; and in the wavelength ranges of 480 nm-600 nm and 600 nm-660 nm, two similar peaks appear respectively, and both the light emitting energy intensities thereof are ≥40%.

The present disclosure further provides a lamp, including a substrate, wherein the substrate is provided with at least one light emitting lamp bead as described in Embodiment 1, and light emitted by the lamp is closer to the sunlight, and provides the good illumination effect for the users.

The above are only preferred embodiments of the present disclosure, and are not intended to limit the present disclosure. For those skilled in the art, the present disclosure has various modifications and changes. Any modifications, equivalent replacements, improvements and the like made within the spirit and principle of the present disclosure should be included in a scope of protection of the present disclosure.

What is claimed is:

1. A light emitting lamp bead, comprising at least one light emitting element and phosphors excited by the at least one light emitting element, wherein a main emission peak wavelength range of each light emitting element is 400 nm-415 nm, and the phosphors comprises a blue phosphor, a green phosphor, a yellow phosphor and a red phosphor.

2. The light emitting lamp bead according to claim 1, wherein a matching ratio of the phosphors according to the mass ratio is: 10%-30% of the blue phosphor; 30%-50% of the green phosphor; 30%-50% of the yellow phosphor; and 5%-15% of the red phosphor.

3. The light emitting lamp bead according to claim 1, wherein the blue phosphor is a blue phosphor with an emission peak wavelength range of 400 nm-480 nm and a full width at half maxima in a range of 50 nm-90 nm.

4. The light emitting lamp bead according to claim 3, wherein the blue phosphor is a blue phosphor with an emission peak wavelength range of 420 nm-460 nm and a full width at half maxima in a range of 50 nm-90 nm.

5. The light emitting lamp bead according to claim 3, wherein the blue phosphor is MgSr₃Si₂O₈:Eu²⁺.

6. The light emitting lamp bead according to claim 1, wherein the green phosphor is a green phosphor with an emission peak wavelength range of 480 nm-520 nm and a full width at half maxima in a range of 50 nm-90 nm.

7. The light emitting lamp bead according to claim 6, wherein the green phosphor is Sr₅(PO₄)₃Cl:Eu²⁺.

8. The light emitting lamp bead according to claim 1, wherein the yellow phosphor is a yellow phosphor with a peak emission wavelength range of 500 nm-560 nm and a full width at half maxima in a range of 90 nm-110 nm.

9. The light emitting lamp bead according to claim 8, wherein the yellow phosphor is Ga-YAG, LuAG or YAG.

10. The light emitting lamp bead according to claim 1, wherein the red phosphor is a red phosphor with a peak emission wavelength range of 590 nm-660 nm and a full width at half maxima in a range of 70 nm-90 nm.

11. The light emitting lamp bead according to claim 10, wherein the red phosphor is CaAlSiN₃:Eu²⁺, or a (Sr/Ca)AlSiN₃:Eu²⁺ co-doped red phosphor.

12. The light emitting lamp bead according to claim 1, wherein a white light emitted by the light emitting lamp bead has a color temperature of 3000K, and a maximum light emitting energy intensity of the white light in the wavelength range of 380 nm-430 nm is below 45%, a maximum light emitting energy intensity of the white light in the wavelength range of 430 nm-480 nm is above 20%, and a maximum light emitting energy intensity of the white light in the wavelength range of 630 nm-650 nm is 100%.

13. The light emitting lamp bead according to claim 1, wherein a white light emitted by the light emitting lamp bead has a color temperature of 5000K, and a maximum light emitting energy intensity of the white light in the wavelength range of 380 nm-430 nm is 100%, a maximum light emitting energy intensity of the white light in the wavelength range of 430 nm-480 nm is above 40%, a maximum light emitting energy intensity of the white light in the wavelength range of 480 nm-600 nm is above 40%, and a maximum light emitting energy intensity of the white light in the wavelength range of 600 nm-660 nm is above 40%.

14. The light emitting lamp bead according to claim 1, wherein a white light emitted by the light emitting lamp bead has a color temperature of 4000K, and a maximum light emitting energy intensity of the white light in the range of 600 nm-700 nm is 100%, a maximum light emitting energy intensity of the white light in the wavelength range of 440nm-460nm is below 60%, and a maximum light emitting energy intensity of the white light in the wavelength range of 460 nm-480 nm is above 60%.

15. A lamp, comprising a substrate, wherein: the substrate is provided with at least one light emitting lamp bead according to claim 1.

16. The light emitting lamp bead according to claim 2, wherein the blue phosphor is a blue phosphor with an emission peak wavelength range of 400 nm-480 nm and a full width at half maxima in a range of 50 nm-90 nm.

17. The light emitting lamp bead according to claim 2, wherein the green phosphor is a green phosphor with an emission peak wavelength range of 480 nm-520 nm and a full width at half maxima in a range of 50 nm-90 nm.

18. The light emitting lamp bead according to claim 2, wherein the yellow phosphor is a yellow phosphor with a peak emission wavelength range of 500 nm-560 nm and a full width at half maxima in a range of 90 nm-110 nm.

19. The light emitting lamp bead according to claim 2, wherein the red phosphor is a red phosphor with a peak emission wavelength range of 590 nm-660 nm and a full width at half maxima in a range of 70 nm-90 nm.

20. The light emitting lamp bead according to claim 2, wherein a white light emitted by the light emitting lamp bead has a color temperature of 3000K, and a maximum light emitting energy intensity of the white light in the wavelength range of 380 nm-430 nm is below 45%, a maximum light emitting energy intensity of the white light in the wavelength range of 430 nm-480 nm is above 20%, and a maximum light emitting energy intensity of the white light in the wavelength range of 630 nm-650 nm is 100%.
